(19) United States
(12) Patent Application Publication
(10) Pub. No.: US 2009/0267195 A1
(43) Pub. Date: Oct. 29, 2009

(54) SEMICONDUCTOR ELEMENT AND METHOD FOR MANUFACTURING SEMICONDUCTOR ELEMENT

(75) Inventor: Tomoaki Kato, Tokyo (JP)

Correspondence Address: YOUNG & THOMPSON, 209 Madison Street, Suite 500, ALEXANDRIA, VA, 22314, US

(73) Assignee: NEC CORPORATION, Tokyo (JP)

(21) Appl. No.: 12/158,155

(22) PCT Filed: Dec. 19, 2006
(86) PCT No.: PCT/JP2006/325243

§ 371 Date: Jun. 19, 2008

(30) Foreign Application Priority Data
Dec. 20, 2005 (JP) 2005-367058

(51) Int. Cl. H01L 29/06; H01L 21/00

(52) U.S. Cl. 257/623; 438/39; 257/E21.002; 257/E29.004

(57) ABSTRACT

A semiconductor device of present invention comprises a layered structure including a cladding layer with a first conductivity, an active layer, and a cladding layer with a second conductivity which are successively grown on a semiconductor substrate of (001) orientation, and an embedding layer covering both side surfaces of the layered structure in a widthwise direction across a longitudinal direction of the layered structure in a plane parallel to a surface of the semiconductor substrate. A portion of side surfaces of the active layer in the widthwise direction lies parallel to at least (010) or (100) surface.

### TECHNICAL FIELD

The present invention relates to a semiconductor device including a semiconductor laser, an optical filter, and a phase modulator, and a method of manufacturing the semiconductor device.

### BACKGROUND ART

In recent years, the explosive increase in the demands for wideband multimedia communication services such as Internet services and video distribution services has been prompting the introduction of longer-distance, larger-capacity, and higher-reliability optical fiber communication systems into trunk networks between cities and metropolitan networks in urban areas. Optical fiber access services such as FTTH (Fiber To The Home), etc. have also been finding widespread usage among subscribers. The wavelength division multiplexing (WDM) technology for multiplexing a plurality of signal lights having different wavelengths for transmission has widely been used in optical fiber communication systems for the purposes of reducing the cost of laying optical fibers as transmission paths and increasing the efficiency with which to utilize the transmission band per optical fiber. Wavelength-division-multiplex optical fiber transmission systems should necessarily have, as their light source, a DFB-LD (Distributed FeedBack-LD: distributed feedback semiconductor laser diode) which is capable of lasing in a single longitudinal mode even upon fast modulation with a grating incorporated in the cavity, or a DBR-LD (Distributed Bragg Reflector: distributed Bragg reflector semiconductor laser diode).

The DFB-LD is available mainly in three structural types, i.e., a lower grating type in which a periodic structure providing a grating is formed below an active layer, an upper grating type in which a periodic structure providing a grating is formed over an active layer, and a structure side wall grating type in which a periodic structure providing a grating is formed on a portion of a side wall of an active layer stripe.

The lower grating type is manufactured by a fabrication process including at least two epitaxial growth steps, i.e., a first epitaxial growth step of forming an active layer on the non-flat surface of a semiconductor substrate with a grating preformed thereon, and a second epitaxial growth step of forming a current blocking layer for embedding both sides of the active layer etched to a striped shape, and realizes a laser diode having a buried heterostructure capable of lasing in a single longitudinal mode.

For diffractively reflecting a light having a particular wavelength with a grating formed on the surface of a semiconductor substrate, it is the general practice to form on the grating an optical waveguide layer having a refractive index that is different from that of the semiconductor substrate. However, when the optical waveguide layer is grown, especially on surface where the grating is formed, a modified layer that has a lattice constant which is different from that of the semiconductor substrate tends to be formed on the surface of the semiconductor substrate while a temperature-increasing standby process immediately prior to the starting of the epitaxial growth. Under an operation, defects and dislocations develop from the modified layer toward the active layer immediately thereabove, possibly impairing crystalline and optical qualities of the active layer. The structure which is widely used at present often includes a spacer layer sandwiched between the active layer and the optical waveguide layer in order to suppress such effects. However, the spacer layer leads to limitations on the leeway in designing structural parameters which govern the optical waveguide characteristics.

The upper grating type is manufactured by a fabrication process including at least three epitaxial growth steps, i.e., a first epitaxial growth step of forming an active layer on the flat surface of a semiconductor substrate, a second epitaxial growth step of forming a grating and then embedding same, and a third epitaxial growth step of forming a current blocking layer for embedding both sides of the active layer etched to a striped shape, and realizes a laser diode having a buried heterostructure laser diode capable of lasing in a single longitudinal mode. For device fabrication reasons, the second and third epitaxial growth steps may be switched around.

The above structure is characterized in that the above problem which tends to be caused by the lower grating type can be eliminated by growing the optical waveguide structure including the active layer altogether onto the flat semiconductor substrate. As a result, the upper grating type is considered to be better than the lower grating type with respect to the crystalline and optical qualities of the active layer and the designing leeway.

However, since the grating is formed on the active layer, any difficulties which can be caused by the etching of the grating and the pretreatment for embedding and growing the grating may possibly affect the active layer. In that case, the structure on the semiconductor substrate to which the high added value of the epitaxial growth is applied is lost, resulting in a yield risk, i.e., a possible reduction in the product yield. The need of at least three step of epitaxial growth is not preferable from the standpoints of lower costs and higher yields. Furthermore, if an n-type semiconductor substrate is employed, then there may occur impaired lasing characteristics due to the inhibition of injection of a carrier into the active layer, caused by impurities such as silicon (Si) atoms which are piled-up and behave as donors on a regrowth interface between a p-type upper optical confinement layer and a p-type embedded cladding layer on the active layer where the grating is formed.

The side wall grating type is manufactured by a fabrication process including at least two epitaxial growth steps, i.e., a first epitaxial growth step of forming an active layer on the flat surface of a semiconductor substrate, and a second epitaxial growth step of forming a current blocking layer for embedding both sides of a striped active layer with a grating formed on side of the active layer, and realizes a laser diode having a buried heterostructure capable of lasing in a single longitudinal mode. Since the side grating type is free of the above problems which may occur with the lower grating type and the upper grating type, the side wall grating type is considered to be more advantageous than the lower and upper grating types from a wide range of standpoints including designing leeway, manufacturing cost, yield, reliability, etc.

For example, JP-A No. 61-279192 (hereinafter referred to as Patent Document 1) discloses that embedding growth is continuously performed after a grating is formed on a side wall of a striped active layer, in order to solve the problem that the grating is disappeared by melt-back when liquid-phase epitaxial growth is performed after a grating is formed on a substrate.

### DISCLOSURE OF THE INVENTION

However, even the technology revealed in Patent Document 1 is guessed to have the side wall grating disappeared by melt-back upon embedding growth after the grating is formed on the side wall of the striped active layer because of the liquid-phase epitaxy. Therefore, the side wall grating structure of Patent Document 1 is not an appropriate choice as long as at least melt-back countermeasures are concerned.

Even if the side wall grating is not melted away, there is another problem, i.e., the effect which the non-flatness of the substrate surface produced after embedding growth may degrade the electrode process yield. Moreover, if the embedding semiconductor layer is used as a current blocking layer, then concern exists over the effect that the embedded configuration has on the current blocking characteristics. In order to solve the above problems and realize a buried heterostructure optical device with the practical side wall grating, the grating on the striped side wall of the active layer has to be made up of a particular crystalline surface. However, Patent Document 1 does not show any specific structural features that the grating on the striped side wall of the active layer need to satisfy, and which are indispensable for solving the above problems.

The buried heterostructure DFB-LD of the side wall grating type disclosed in Patent Document 1 belongs to the background art suffering from the above structural and characteristic problems. No effective solutions have been proposed yet up to present. In view of the above background, except for few exceptions in which a grating is formed on a ridge side wail of a ridge-type LD that is free of a current blocking structure, there have not been any reports on a grating formed on a side of a semiconductor laser diode and a buried heterostructure of the side wall grating has not yet been put to practical use at present.

It is an object of the present invention, which has been made in view of the above problems, to provide a semiconductor device which improves the flatness of the shape of an embedding layer formed on a semiconductor substrate for improving a fabrication process yield, electrical and optical characteristics, and reliability, and a method of manufacturing such a semiconductor device.

To achieve the above object, there is provided in accordance with the present invention a semiconductor device comprising a layered structure including a cladding layer with a first conductivity, an active layer, and a cladding layer with a second conductivity which are successively grown on a semiconductor substrate of (001) orientation, and an embedding layer covering both side surfaces of the layered structure in a widthwise direction across a longitudinal direction of the layered structure in a plane parallel to a surface of the semiconductor substrate, wherein a portion of side surfaces of the active layer in the widthwise direction lies parallel to at least (010) or (100) surface.

With respect to the relative relationship between the crystal orientations of the semiconductor substrate and the side surfaces of the layered structure, the orientation of the surface of the semiconductor substrate on which the layered structure and the embedding layer are formed is parallel to (001) and the portion of the side surfaces of the active layer lies parallel to (010) or (100) surface. Therefore, embedding growth process for growing the embedding layer while the surface of the embedding layer is kept parallel to the surface of the semiconductor substrate and fiat.

In the semiconductor device according to the present invention, a first contact layer with the second conductivity may be grown as an uppermost layer of the layered structure, a second contact layer with the second conductivity may be grown as an uppermost layer of the embedding layer, and the first contact layer and the second contact layer may have side surfaces held against each other.

The semiconductor device according to the present invention may further comprise an embedding cladding layer with the second conductivity which covers upper surfaces of the layered structure and the embedding layer.

In the semiconductor device according to the present invention, a structure comprising an alternate repetition of surfaces parallel to (010) and (100) surfaces may be provided in a portion of the side surfaces of the active layer in the widthwise direction.

In the semiconductor device according to the present invention, the side surfaces of the layered structure in the widthwise direction may be plane-symmetrical with respect to a plane extending through a longitudinal axis of the layered structure and perpendicular to the surface of the semiconductor substrate.

In the semiconductor device according to the present invention, the embedding layer may include a semi-insulating semiconductor covering at least the side surfaces of the active layer. The semi-insulating semiconductor may contain at least iron or ruthenium.

To achieve the above object, there is also provided in accordance with the present invention a method of manufacturing a semiconductor device, comprising forming a multilayer structure including a structure comprising a cladding layer with a first conductivity, an active layer, and a cladding layer with a second conductivity which are successively grown on a semiconductor substrate of (001) orientation, forming, on the multilayer structure, a mask for forming a predetermined pattern on the multilayer structure, the mask having a shape parallel to at least (010) or (100) surface in a portion of a side of the predetermined pattern in a widthwise direction across a longitudinal direction of the predetermined pattern in a plane parallel to a surface of the semiconductor substrate, etching the multilayer structure from above the mask to form a layered structure according to the predetermined pattern, and forming an embedding layer covering both side surfaces of the layered structure.

According to the present invention, at least a portion of side surfaces of the active layer in a widthwise direction lies parallel to at least (010) or (100) surface. Therefore, the embedding layer can be grown by way of embedding growth while the surface of the embedding layer is kept parallel to the substrate, and irregularities of the substrate surface after completion of the embedding growth are held to a minimum.

Consequently, the yield of a process of manufacturing a semiconductor device such as a DFB-LD of a buried heterostructure having a grating on side surfaces of an active layer in a widthwise direction, electrical and optical characteristics, and reliability can be improved.

### BRIEF DESCRIPTION OF THE DRAWINGS

FIG. 1A is a cross-sectional view of a structure of a semiconductor device according to a first exemplary embodiment, taken along a direction perpendicular to the plane of a substrate;

FIG. 1B is a cross-sectional view of the structure of the semiconductor device according to the first exemplary embodiment, taken along a direction parallel to the plane of the substrate;

FIG. 2A is a plan view showing different orientations of side surfaces of the layered structures of a semiconductor device according to a structural example of the present invention and a semiconductor device according to the background art;

FIG. 2B is a cross-sectional view of the layered structure according to the background art which is produced by embedding growth;

FIG. 2C is a cross-sectional view of the layered structure according to the structural example of the present invention which is produced by embedding growth;

FIG. 3A is a cross-sectional view of a structure produced upon completion of a first epitaxial growth step in a method of manufacturing the semiconductor device according to the first exemplary embodiment;

FIG. 3B is a cross-sectional view of a structure processed into a stripe by etching after the step shown in FIG. 3A in the method of manufacturing the semiconductor device according to the first exemplary embodiment;

FIG. 3C is a cross-sectional view of a structure produced upon completion of an embedding growth step after the step shown in FIG. 3B in the method of manufacturing the semiconductor device according to the first exemplary embodiment;

FIG. 4A is a perspective view of a structure produced after an optical waveguide structure has grown on the entire surface of a semiconductor substrate in a general example of the method of manufacturing of the semiconductor device according to the first exemplary embodiment and its structure;

FIG. 4B is a perspective view of a structure produced after the structure shown in FIG. 4A has been processed into a mesastripe;

FIG. 4C is a perspective view of a structure produced upon completion of an embedding growth step on the structure shown in FIG. 4B;

FIG. 5A is a cross-sectional view of a structure of a DFB-LD according to Example 1, taken along a direction perpendicular to the plane of a substrate;

FIG. 5B is a cross-sectional view of the structure of the DFB-LD according to Example 1, taken along a direction parallel to the plane of the substrate;

FIG. 6A is a cross-sectional view of a structure produced upon completion of a first epitaxial growth step in a method of manufacturing the DFB-LD according to Example 1;

FIG. 6B is a cross-sectional view of a structure processed into a stripe by etching after the step shown in FIG. 6A in the method of manufacturing the DFB-LD according to Example 1;

FIG. 6C is a cross-sectional view of a structure produced upon completion of an embedding growth step after the step shown in FIG. 6B in the method of manufacturing the DFB-LD according to Example 1;

FIG. 7A is a cross-sectional view of a structure of a semiconductor optical filter according to Example 2, taken along a direction perpendicular to the plane of a substrate;

FIG. 7B is a cross-sectional view of the structure of the semiconductor optical filter according to Example 2, taken along a direction parallel to the plane of the substrate;

FIG. 8A is a cross-sectional view of a structure produced upon completion of a first epitaxial growth step in a method of manufacturing the semiconductor optical filter according to Example 2;

FIG. 8B is a cross-sectional view of a structure processed into a stripe by etching after the step shown in FIG. 8A in the method of manufacturing the semiconductor optical filter according to Example 2;

FIG. 8C is a cross-sectional view of a structure produced upon completion of an embedding growth step after the step shown in FIG. 8B in the method of manufacturing the semiconductor optical filter according to Example 2;

FIG. 9A is a cross-sectional view of a structure of a semiconductor device according to a second exemplary embodiment, taken along a direction perpendicular to the plane of a substrate;

FIG. 9B is a cross-sectional view of the structure of the semiconductor device according to the second exemplary embodiment, taken along a direction parallel to the plane of the substrate;

FIG. 10A is a cross-sectional view of a structure produced upon completion of a first epitaxial growth step in a method of manufacturing the semiconductor device according to the second exemplary embodiment;

FIG. 10B is a cross-sectional view of a structure processed into a stripe by etching after the step shown in FIG. 10A in the method of manufacturing the semiconductor device according to the second exemplary embodiment;

FIG. 10C is a cross-sectional view of a structure produced upon completion of an embedding growth step after the step shown in FIG. 10B in the method of manufacturing the semiconductor device according to the second exemplary embodiment;

FIG. 11A is a cross-sectional view of a structure of a DFB-LD according to Example 3, taken along a direction perpendicular to the plane of a substrate;

FIG. 11B is a cross-sectional view of the structure of the DFB-LD according to Example 3, taken along a direction parallel to the plane of the substrate;

FIG. 12A is a cross-sectional view of a structure produced upon completion of a first epitaxial growth step in a method of manufacturing the DFB-LD according to Example 3;

FIG. 12R is a cross-sectional view of a structure processed into a stripe by etching after the step shown in FIG. 12A in the method of manufacturing the DFB-LD according to Example 3;

FIG. 12C is a cross-sectional view of a structure produced upon completion of an embedding growth step after the step shown in FIG. 12B in the method of manufacturing the DFB-LD according to Example 3;

FIG. 13A is a cross-sectional view of a structure of a semiconductor optical filter according to Example 4, taken along a direction perpendicular to the plane of a substrate;

FIG. 13B is a cross-sectional view of the structure of the semiconductor optical filter according to Example 4, taken along a direction parallel to the plane of the substrate;

FIG. 14A is a cross-sectional view of a structure produced upon completion of a first epitaxial growth step in a method of manufacturing the semiconductor optical filter according to Example 4;

FIG. 14B is a cross-sectional view of a structure processed into a stripe by etching after the step shown in FIG. 14A in the method of manufacturing the semiconductor optical filter according to Example 4;

FIG. 14C is a cross-sectional view of a structure produced upon completion of an embedding growth step after the step shown in FIG. 14B in the method of manufacturing the semiconductor optical filter according to Example 4;

FIG. 15A is a cross-sectional view of a structure of a semiconductor optical filter according to Example 5, taken along a direction perpendicular to the plane of a substrate;

FIG. 15B is a cross-sectional view of the structure of the semiconductor optical filter according to Example 5, taken along a direction parallel to the plane of the substrate;

FIG. 16A is a cross-sectional view of a structure produced upon completion of a first epitaxial growth step in a method of manufacturing the semiconductor optical filter according to Example 5;

FIG. 16B is a cross-sectional view of a structure processed into a stripe by etching after the step shown in FIG. 16A in the method of manufacturing the semiconductor optical filter according to Example 5;

FIG. 16C is a cross-sectional view of a structure produced upon completion of an embedding growth step after the step shown in FIG. 16B in the method of manufacturing the semiconductor optical filter according to Example 5; and

FIG. 16D is a cross-sectional view of a structure produced upon completion of an electrode formation after the step shown in FIG. 16C in the method of manufacturing the semiconductor optical filter according to Example 5.

### DESCRIPTION OF REFERENCE CHARACTERS

101, 131, 201, 501 semiconductor substrate
111, 121 layered structure
112, 122 growth prevention mask
113, 123 embedding growth layer
132 cladding layer with first electric conductivity
133 active layer
134, 205, 505 cladding layer with second electric conductivity
135 hetero-barrier relaxation layer
136 contact layer
141, 208, 310, 410, 507 mesastripe
151, 209, 508 embedding layer
202, 502 lower optical confinement layer with first electric conductivity
203, 503 undoped core layer
204, 504 upper optical confinement layer with second electric conductivity
206, 510 contact layer with second electric conductivity
207, 309, 409, 506, 607, 707, 807 mask
210, 511 insulating film
211, 212, 512, 513 electrode
301, 401 n-InP substrate
302, 402 n-InP cladding layer
303, 403 n-InGaAsP lower optical confinement layer
304, 404 undoped InGaAsP strained multiple quantum well active layer
305, 405 p-InGaAsP upper optical confinement layer
306, 406, 314, 414 p-InP cladding layer
307, 407, 315, 415 p-InGaAsP hetero-barrier relaxation layer
308, 408, 316, 416 p⁺-InGaAs contact layer
311, 411 p-InP electron trapping layer
312, 412 Ru-doped semi-insulating InP current blocking layer
313, 413 n-InP hole trapping layer
317, 417, 616, 716, 816 separation groove
318, 418, 617, 717, 817 SiO₂ film
319, 320, 419, 420 Ti—Pt—Au electrode
509 embedding cladding layer with second electric conductivity
601, 701, 801 n-InP substrate
602, 702, 802 n-InP cladding layer
603, 703, 803 n-InGaAsP lower optical confinement layer
604, 704, 804 undoped InGaAsP strained multiple quantum well active layer
605, 705, 805 p-InGaAsP upper optical confinement layer
606, 706, 806 p-InP cladding layer
608, 708, 808 mesastripe
609, 709, 809 p-InP electron trapping layer
610, 710, 810 Ru-doped semi-insulating InP current blocking layer
611, 711, 811 n-InP hole trapping layer
612, 712, 812 n-InP cladding layer
613, 713, 813 p-InP overcladding layer
614, 714, 814 p-InGaAsP hetero-barrier relaxation layer
615, 715, 815 p⁺-InGaAs contact layer
618, 619, 718, 719, 818, 819 Ti—Pt—Au electrode

### BEST MODE FOR CARRYING OUT THE INVENTION

Best exemplary embodiments of the present invention will be described below with reference to the drawings. In the exemplary embodiments described below, the present invention is applied to an embedded-type semiconductor device having a double heterostructure.

### 1st Exemplary Embodiment

A first exemplary embodiment of the present invention will be described below with reference to the drawings.

First, the structure of a semiconductor device according to the first exemplary embodiment will be described below.

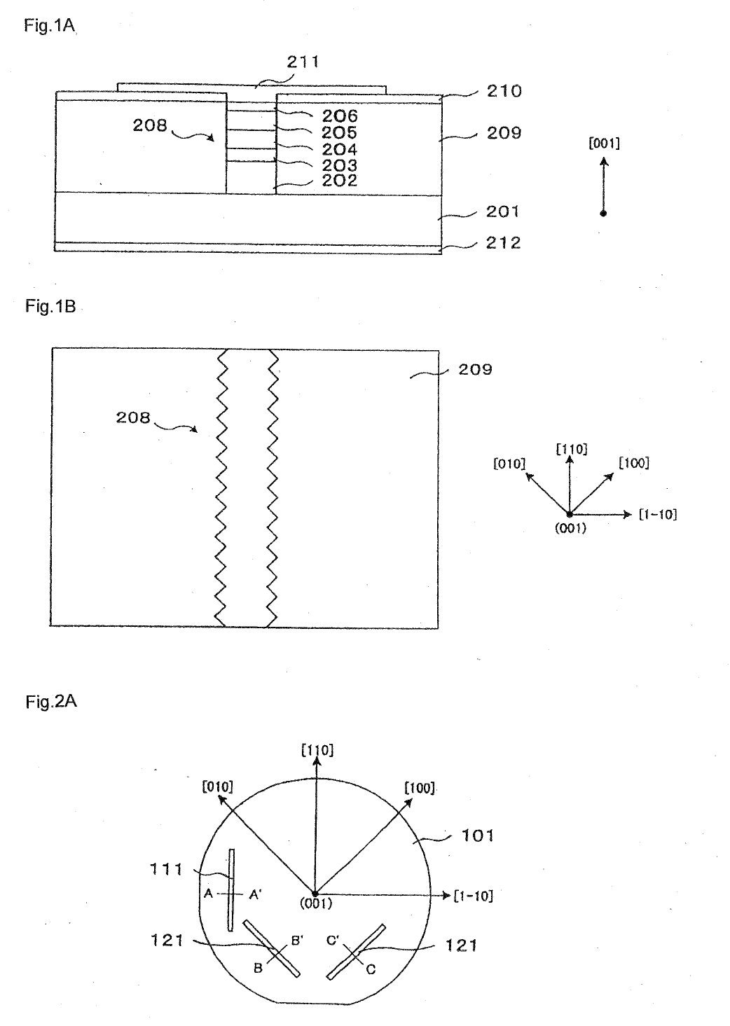

FIGS. 1A and 1B are cross-sectional views of the structure of the semiconductor device according to the first exemplary embodiment. FIG. 1A is taken along a direction perpendicular to the plane of a substrate, and FIG. 1B along a direction parallel to the plane of the substrate.

As shown in FIG. 1A, the semiconductor device according to the first exemplary embodiment includes mesastripe 208 comprising lower optical confinement layer 202 with a first electric conductivity, undoped core layer 203, upper optical confinement layer 204 with a second electric conductivity, cladding layer 205 with the second electric conductivity, and contact layer 206 with the second electric conductivity, which are successively grown on semiconductor substrate 201 of (001) orientation Undoped core layer 203 is an example of an active layer, and mesastripe 208 is an example of a layered structure. Contact layer 206 with the second electric conductivity is provided to decrease the contact resistance between electrode 211 and cladding layer 205 with the second electric conductivity.

As shown in FIG. 1B, mesastripe 208 has side walls formed with a grating having a periodic structure which is made up of an alternate repetition of surfaces parallel to (010) and (100) planes. The side walls of mesastripe 208 are embedded in embedding layer 209 having a current blocking capability. Embedding layer 209 has an upper surface covered with insulating film 210. Electrodes 211, 212 for injecting carriers into undoped core layer 203 or applying an electric field to undoped core layer 203 are formed respectively on upper and lower surfaces of the semiconductor device. Semiconductor substrate 201 acts as a cladding layer with the first electric conductivity.

Advantages of the semiconductor device according to the present invention will be described below in comparison with a semiconductor device according to the background art. For illustrative purposes, it is assumed that side surfaces of the pattern of the layered structure which lie in widthwise directions perpendicular to the longitudinal direction of the pattern are of a simple planar shape.

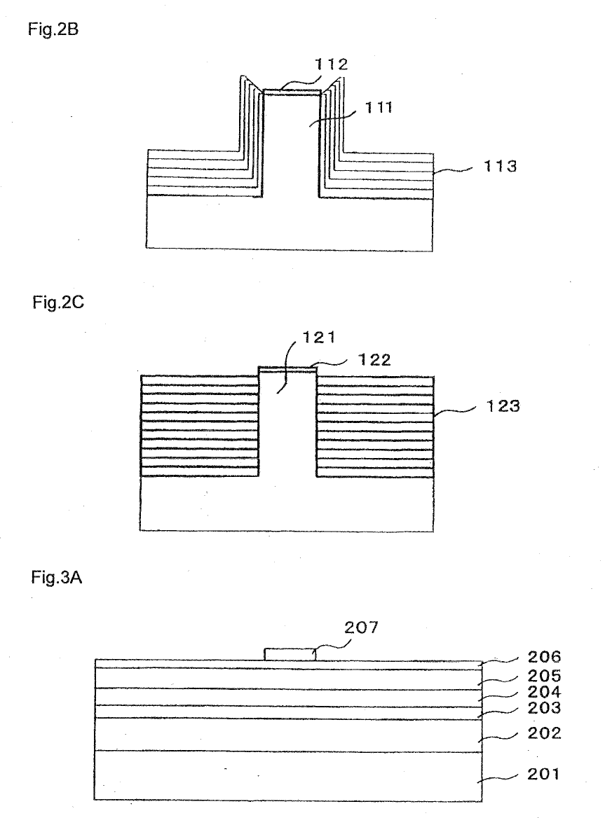

FIG. 2A is a plan view showing different orientations of side surfaces of the layered structures of a semiconductor device according to a structural example of the present invention and a semiconductor device according to the background art. FIG. 2B is a cross-sectional view of the layered structure according to the background art which is produced by embedding growth, taken along line A-A′ of FIG. 2A. FIG. 2C is a cross-sectional view of the layered structure according to the structural example of the present invention which is produced by embedding growth, taken along line B-B′ or C-C′ of FIG. 2A.

As shown in FIG. 2A, layered structure 111 according to the background art is formed on semiconductor substrate 101 of (001) orientation such that the layered structure has side surfaces lying parallel to (110) or (1-10) orientation. Therefore, upon embedding growth with growth prevention mask 112 on layered structure 111, as shown in FIG. 2B, embedding growth layer 113 is grown in [001] direction and is also grown abnormally in directions perpendicular to the side surfaces of the layered structure, tending to impair the surface planarity of the semiconductor substrate upon completion of embedding growth.

As shown in FIG. 2A, layered structure 121 according to the structural example of the present invention is formed such that the layered structure has side surfaces lying parallel to plane (010) or (100). Therefore, upon embedding growth with growth prevention mask 121 on layered structure 121, as shown in FIG. 2C, abnormal growth near the layered structure is suppressed. As a result, it is possible to grow the embedding layer while keeping its surface parallel to the semiconductor substrate, minimizing roughness on the substrate surface upon completion of embedding growth.

As shown in FIG. 2A, the pattern of layered structure 111 has a longitudinal axis parallel to [110] axis, and the pattern of layered structure 121 according to the structural example of the present invention has a longitudinal axis parallel to by [010] or [100] axis.

A method of manufacturing the semiconductor device according to the first exemplary embodiment will be described below.

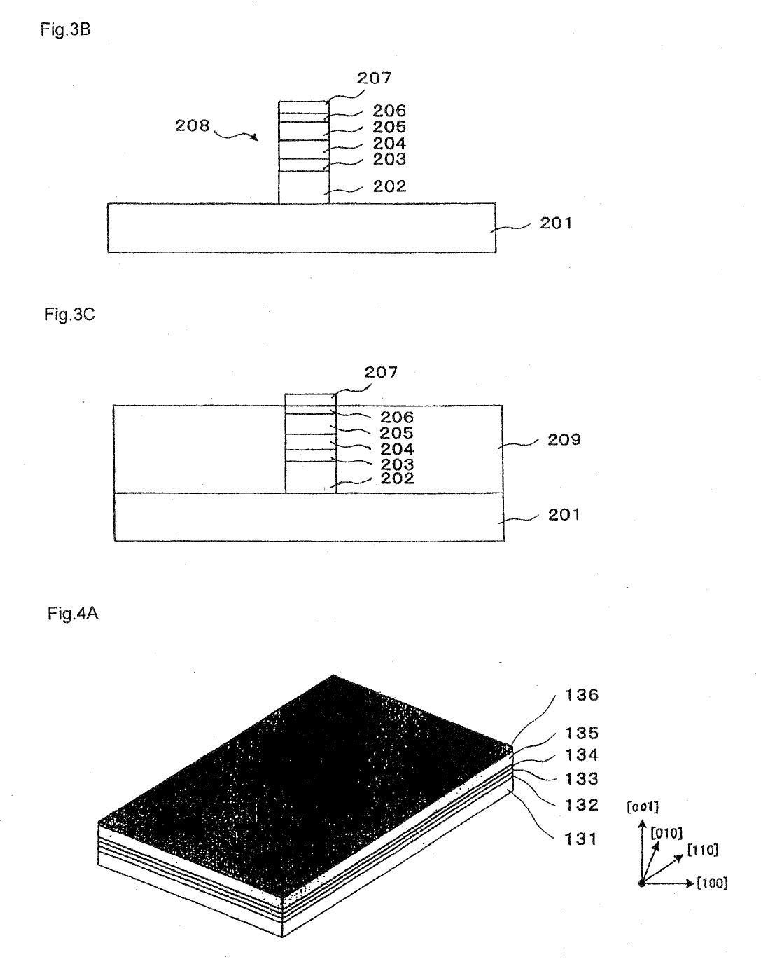

FIGS. 3A through 3C are cross-sectional views illustrative of a method of manufacturing the semiconductor device according to the first exemplary embodiment. FIG. 3A is a view showing a structure produced upon completion of a first epitaxial growth step, FIG. 3B is a view showing a structure processed into a stripe by etching, and FIG. 3C is a view showing a structure produced upon completion of an embedding growth step.

First, as shown in FIG. 3A, optical confinement layer 202, undoped core layer 203, optical confinement layer 204, cladding layer 205, and contact layer 206 are successively grown continuously to form mesastripe 208 by a first epitaxial growth step employing metalorganic vapor phase epitaxy (MOVPE) or the like.

After a mask pattern, not shown, is transferred to mask 207 by a lithography such as electron beam exposure and reactive ion etching (RIE), the wafer is etched by two-frequency RF-excited inductively coupled plasma reactive ion etching (ICP-RIE) or the like which is of excellent verticality, smoothness, and low-damage, thereby forming on both side walls of mesastripe 208 a grating made up of an alternate repetition of surfaces parallel to (010) and (100) planes (FIG. 3B).

Thereafter, as shown in FIG. 3C, embedding layer 209 is formed by a second epitaxial growth employing MOVPE or the like.

In the actual embedding growth step, even when the relative relationship between the crystal orientations of the upper surface of semiconductor substrate 201 and the side surfaces of mesastripe 208 is determined as described above, embedding layer 209 is formed as thin layers on the overall side surfaces of mesastripe 208 at the same time that it is grown in a direction perpendicular to the upper surface of the substrate. The side surface growth layers possibly behave as a path through which the injected carrier leaks or as a factor for preventing the carrier from being injected into the active layer, and are not preferable from the standpoints of the device characteristics and reliability. In particular, if the embedding layer is of a multilayer structure, then since the side surface growth layers themselves are necessarily of a multilayer structure reflecting the structure of the embedding growth layer, their behavior is complicated, making it difficult to accurately estimate effects on the lasing characteristics.

If the above concern can be removed in advance, i.e., if the side surface growth layers can be removed by any means during the embedding growth step, then it is possible to remove the causes of the current leakage and the prevention of the carrier injection while maximizing the advantages of flat embedding growth. Therefore, such a means is highly useful. According to the most practical method to provide such a means, an appropriate amount of etching gas is injected into the reactor of an epitaxial growth apparatus for each interface of the embedding growth layer of the multilayer structure, and the thin embedding growth layers formed on the side surfaces of mesastripe 208 are removed by “in-situ etching”.

The greater the ratio of the etching rate in the directions of the side surfaces of mesastripe 208 and that in the direction in which the layers are grown on semiconductor substrate 201, the more advantageous it is to increase the controllability of the etching quantity. If the relative relationship between the crystal surface orientations of semiconductor substrate 201 and the side surfaces of mesastripe 208 is determined as described above, then the former etching rate may be made at least twice the latter etching rate by choosing suitable etching conditions. Therefore, it is sufficiently possible to effectively remove only unwanted side surface growth layers during the embedding growth step while maintaining the multilayer structure in which the layers are vertically grown on semiconductor substrate 201.

The in-situ etching, which enables the side surfaces of mesastripe 208 to be ideally clean and flat for epitaxial growth, is expected to double as part of a pretreatment for the embedding growth step and to contribute in some way to the reduction of a scattering loss of a signal light that propagates through mesastripe 208. An etching gas for use in the etching process may be a typical halogen compound for vapor phase epitaxy, such as CBr₄ (tetrabromomethane), TBCl (tertiarybutylchloride), or BDMAPCl (Bis(demethylamino)phosphine chloride).

After embedding layer 209 is formed, mask 207 is removed, and insulating film 210 is formed on the upper surface. Then, electrode 211 and electrode 212 are formed, thus completing the semiconductor device shown in FIGS. 1A and 1B.

The manufacturing process and structure of the semiconductor device according to the present exemplary embodiment will be described below with reference to perspective views.

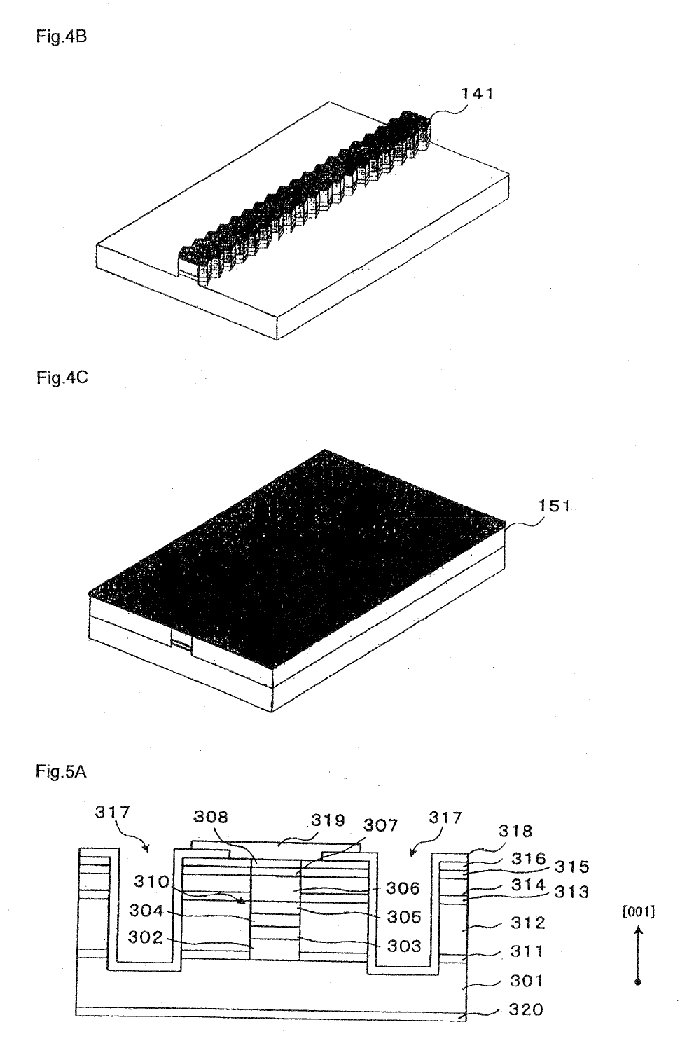

FIG. 4A is a perspective view of a structure produced after an optical waveguide structure has grown on the entire surface of a semiconductor substrate, FIG. 4B is a perspective view of a structure produced after the structure shown in FIG. 4A has been processed into a mesastripe, and FIG. 4C is a perspective view of a structure produced upon completion of an embedding growth step on the structure shown in FIG. 4B.

First, cladding layer 132 with a first electric conductivity, active layer 133, cladding layer 134 with a second electric conductivity, hetero-barrier relaxation layer 135, and contact layer 136 are formed by way of epitaxial growth on semiconductor substrate 131 of a plane orientation parallel to plane (001), forming an optical waveguide structure (FIG. 4A). The layered structure with these films corresponds to a multilayer structure according to the present invention.

A mask for forming the waveguide stripe is formed on the multilayer structure, and the layered structure is etched into a mesastripe with an alternate repetition of surfaces parallel to (010) and (100) planes. Thereafter, embedding layer 151 is formed by embedding growth, thus completing a semiconductor device shown in FIG. 4C.

The mask for forming the pattern of a layered structure has a shape corresponding to the pattern of the layered structure, i.e., made up of an alternate repetition of surfaces parallel to (010) and (100) planes, on sides in widthwise directions perpendicular to the longitudinal direction of the pattern.

In FIG. 4B, the entire side surfaces of the layered structure are of a structure parallel to a repetition of plane (010) and plane (100). However, the side surfaces may partly be of a repetitive structure.

Since the side surfaces of the layered structure are partly of a structure parallel to a repetition of plane (010) and plane (100), when they are embedded by an embedding layer which serves both to block a current and to confine light, there is realized a grating required for lasing in a single longitudinal mode while minimizing roughness on the substrate surface after the embedding growth is completed.

As shown in FIG. 4B, the side surfaces of the layered structure should preferably be plane-symmetrical with respect to a plane extending through the longitudinal axis of the pattern of the layered structure and perpendicular to plane (001) of semiconductor substrate 131. This structure is suitable as a single mode waveguide from the view points of propagation characteristics because its dominant mode is also plane-symmetrical.

Operation of the semiconductor device according to the first exemplary embodiment will be described below with reference to FIG. 1A.

When an electric current is injected into the semiconductor device from electrode 211 serving as an anode to electrode 212 as a cathode, holes are injected from optical confinement layer 204 into undoped core layer 203, and electrons are injected from optical confinement layer 202 into undoped core layer 203. The holes and the electrons are recombined with each other in undoped core layer 203, emitting light. Light having a particular wavelength which is determined by the periodic of the grating on the side surfaces of mesastripe 208 and the effective refractive index of mesastripe 208 is amplified, causing the semiconductor device to oscillate in a single longitudinal mode.

According to the present exemplary embodiment, as described above, since the side surfaces of undoped core layer 203 are formed so as to be parallel to at least one of plane (010) and plane (100), the embedding layer 209 is grown in the second epitaxial growth step while its surface lies substantially parallel to the surface of semiconductor substrate 201 and remains flat. As a result, upon completion of the embedding growth, the surface of the semiconductor device is free of irregularities caused by abnormal growth near mesastripe 208 and is as flat as practically free of problems in an electrode process.

The actual embedding growth layer is generally of a multilayer structure including different layers for trapping electrons and holes. The present exemplary embodiment is also applicable to such a structure.

According to the present exemplary embodiment, the side surfaces of mesastripe 208 are of a periodic structure which is made up of an alternate repetition of surfaces parallel to (010) and (100) planes. When the periodic structure is embedded with embedding layer 209 which serves both to block a current and to confine light, there is realized a grating required for lasing in a single longitudinal mode. Accordingly, a single longitudinal mode LD having a buried heterostructure that is advantageous for improved lasing characteristics can be realized in at least two epitaxial growth steps.

The side surface grating structure allows an active layer and all semiconductor layers required to inject a carrier into the active layer to be continuously grown on a flat semiconductor substrate. Therefore, the semiconductor device is structurally capable of eliminating deficiencies caused by the epitaxial growth step, such as crystalline degradation and carrier injection failures of the active layer, which tend to occur in the lower grating type and the upper grating type according to the background art.

According to the present exemplary embodiment, furthermore, the axis in the longitudinal direction (hereinafter referred to as “longitudinal axis”) of the pattern of mesastripe 208 extends parallel to [110] axis. Even if the longitudinal axis extends parallel to [1-10] axis, the grating on the side surface is of a periodic structure which is made up of an alternate repetition of surfaces parallel to (010) and (100) planes. Therefore, the semiconductor device wherein the longitudinal axis of mesastripe 208 extends parallel to [110] axis and the semiconductor device wherein the longitudinal axis of mesastripe 208 extends parallel to [1-10] axis are geometrically and crystallographically equivalent to each other. In other words, an auxiliary advantage that devices that are angularly spaced 90° from each other are identical to each other is produced. This advantage overcomes the common sense of a method of manufacturing a compound optical semiconductor device according to the background art wherein the longitudinal axis of the active layer stripe has to extend in a particular direction, and is effective to increase the freedom of a device layout for the fabrication of optical integrated devices.

### Example 1

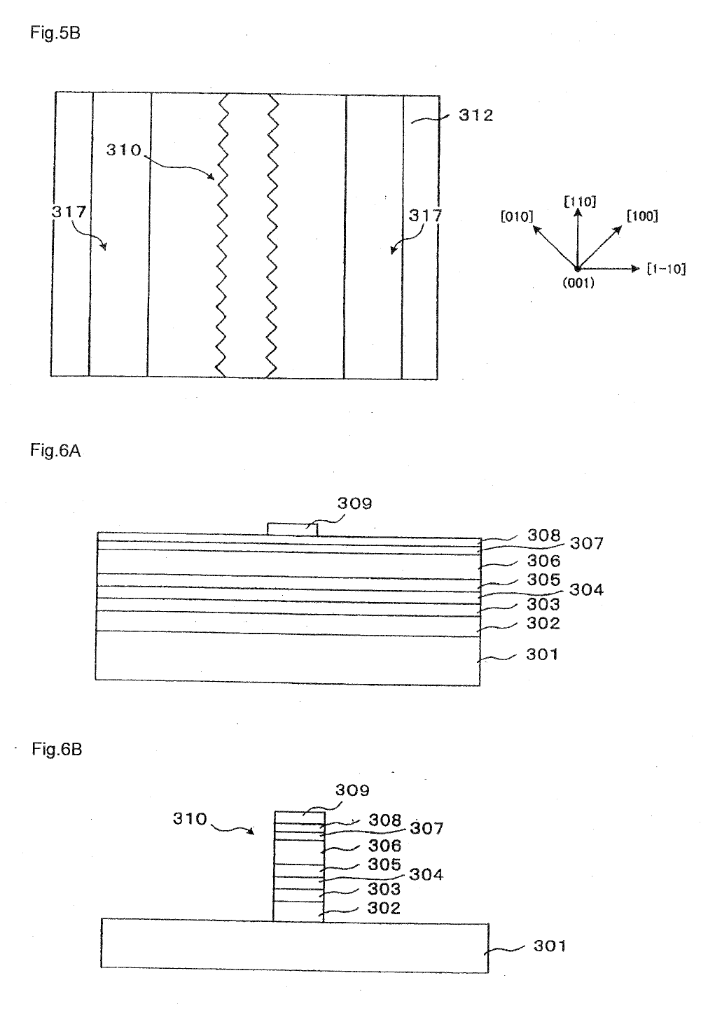

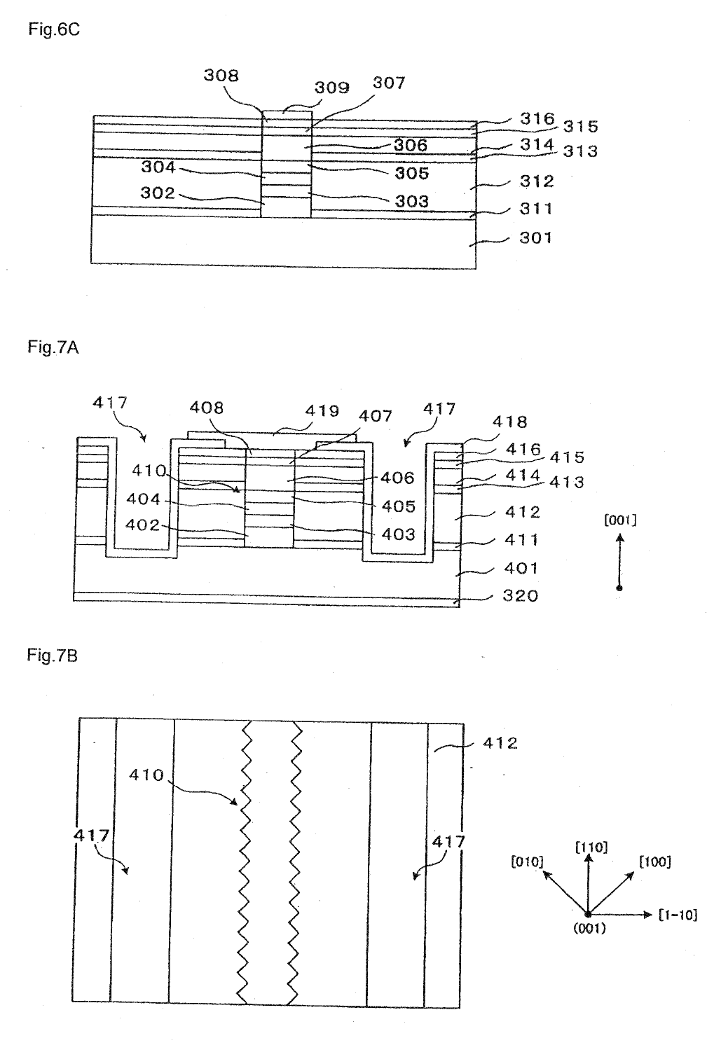

An example of a DFB-LD used to verify the semiconductor device according to the first exemplary embodiment will be described below with reference to FIGS. 5A, 5B and 6A through 6C.

First, the structure of the DFB-LD according to Example 1 will be described below.

FIGS. 5A and 5B are cross-sectional views showing the structure of the DFB-LD according to Example 1. FIG. 5A is a cross-sectional view taken along a direction perpendicular to the plane of a substrate, and FIG. 5B is a cross-sectional view taken along a direction parallel to the plane of the substrate.

As shown in FIG. 5A, the DFB-LD according to Example 1 includes mesastripe 310 comprising n-InP cladding layer 302, n-InGaAsP lower optical confinement layer 303, undoped InGaAsP strained multiple quantum well active layer 304, p-InGaAsP upper optical confinement layer 305, p-InP cladding layer 306, p-InGaAsP hetero-barrier relaxation layer 307, and p⁺-InGaAs contact layer 308 which are successively grown on n-InP substrate 301 of (001) orientation.

n-InP substrate 301 of (001) orientation is an example of a substrate. n-InP cladding layer 302 is an example of a cladding layer with a first electric conductivity. p-InP cladding layer 306 is an example of a cladding layer with a second electric conductivity. Mesastripe 310 is an example of a layered structure.

In the present example, n-InGaAsP lower optical confinement layer 303 has a wavelength composition of 1250 nm, undoped InGaAsP strained multiple quantum well active layer 304 has a transition wavelength of 1560 nm, p-InGaAsP upper optical confinement layer 305 has a wavelength composition of 1250 nm, and p-InGaAsP hetero-barrier relaxation layer 307 has a wavelength composition of 1400 nm.

As shown in FIG. 5B, mesastripe 310 has side walls formed with a grating having a periodic of 240 nm which is made up of an alternate repetition of surfaces parallel to (010) and (100) planes at respective intervals of 120 nm along (110) orientation. An effective stripe width produced by averaging the corrugation of the side walls is 1.3 μm.

An embedding layer which embeds both the side walls of mesastripe 310 comprises a set of p-InP electron trapping layer 311, Ru-doped semi-insulating InP current blocking layer 312, n-InP hole trapping layer 313, p-InP cladding layer 314, p-InGaAsP hetero-barrier relaxation layer 315, and p⁺-InGaAs contact layer 316.

The semi-insulating semiconductor added as part of the embedding layer is effective in not only suppressing current leakage, but also reducing a parasitic capacitance with other insulative films for making modulation speed faster. Ru (ruthenium) is an ideal dopant, among other dopants, which is not decomposed by a hydrogen gas used for epitaxial growth and remains stable, and which undergoes low solid-phase interdiffusion with Zn (zinc) at the epitaxial growth temperature. Therefore, when ruthenium is used as a dopant for a semi-insulating semiconductor, it is possible to produce a semi-insulating semiconductor whose insulating characteristics are stable against variations of the temperature in the fabrication process.

Separation grooves 317 for reducing the device capacitance and electrically separating adjacent channels from each other are formed on both sides of mesastripe 310. SiO₂ films 318 are formed over separation grooves 317. Ti—Pt—Au electrodes 319, 320 are formed for injecting a carrier into undoped InGaAsP strained multiple quantum well active layer 304.

The cavity length is 250 μm with a front end face coated with a low reflection film (not shown) and a rear end face coated with a high reflection film (not shown). The K L product is 1.2.

A method of manufacturing the DFB-LD according to Example 1 will be described below.

FIGS. 6A through 6C are cross-sectional views showing the method of manufacturing the DFB-LD according to Example 1. FIG. 6A is a view showing a structure produced upon completion of a first epitaxial growth step, FIG. 6B is a view showing a structure processed into a stripe by etching, and FIG. 6C is a view showing a structure produced upon completion of an embedding growth step.

First, n-InP cladding layer 302, n-InGaAsP lower optical confinement layer 303, undoped InGaAsP strained multiple quantum well active layer 304, p-InGaAsP upper optical confinement layer 305, p-InP cladding layer 306, p-InGaAsP hetero-barrier relaxation layer 307, and p⁺-InGaAs contact layer 308 are successively grown continuously on n-InP substrate 301 to form mesastripe 310 by a first epitaxial growth step employing MOVPE.

Then, an SiO₂ film serving as etching mask 309 is patterned with high accuracy according to electron beam exposure and RIE (FIG. 6A). Then, the grating is formed with high accuracy according to ICP-RIE, as shown in FIG. 6B.

Thereafter, p-InP electron trapping layer 311, Ru-doped semi-insulating InP current blocking layer 312, n-InP hole trapping layer 313, p-InP cladding layer 314, p-InGaAsP hetero-barrier relaxation layer 315, and p⁺-InGaAs contact layer 316 are successively grown continuously to form an embedding layer by a second epitaxial growth step employing MOVPE (FIG. 6C).

An unwanted embedding layer that is grown as a thin layer on the side surfaces of mesastripe 310 upon embedding growth is removed as follows: At the time the boundary surface of each layer is reached when an unwanted embedding layer is about to form, the supply of a group III source material is stopped to interrupt the embedding growth. A halogen compound of BDMAPCl is added to a group V source material, and in-situ etching is performed to remove any unwanted embedding layer which may have been formed at the time. Thereafter, the supply of the group III source material is resumed to grow a layer immediately above the latest layer. The above process is repeated to remove an unwanted embedding layer.

According to the above technique, each of p-InP cladding layer 306, p-InGaAsP hetero-barrier relaxation layer 307, and p⁺-InGaAs contact layer 308 which are formed in the first epitaxial growth step and each of p-InP cladding layer 314, p-InGaAsP hetero-barrier relaxation layer 315, and p⁺-InGaAs contact layer 316 which are formed in the second epitaxial growth step make up a structure wherein adjacent layers are held against each other seamlessly. The contact layer of the layered structure and the contact layer of the embedding layer are held in contact with each other with no unwanted embedding layer interposed therebetween, preventing the contact resistance from increasing. Since the adjacent layers are held in contact with each other with a low resistance therebetween, the injection of a carrier into the active layer is prevented from being impaired for increased device characteristics and reliability.

Ru-doped semi-insulating InP current blocking layer 312 is made of bisethylcyclopentadienyl ruthenium ((EtCp)2Ru). ((EtCp)2Ru) is used as a source material of ruthenium compound because it is less liable to suffer aging and it is less reactive and stabler except for doping, than other source materials.

After mask 309 is removed, the wafer is etched through the embedding layer on the sides of mesastripe 310, thereby forming separation grooves 317. Then, SiO₂ film 318 is formed on the upper surface, and subsequently removed primarily from the upper surface of mesastripe 310. Thereafter, Ti—Pt—Au electrodes 319, 320 are formed.

In this manner, the FDB-LD shown in FIGS. 5A and 5B is completed.

When a carrier was injected into undoped InGaAsP strained multiple quantum well active layer 304, the FDB-LD oscillated in a single axis mode with a threshold current of 5 mA and an oscillation wavelength of 1550 nm at 250C. The FDB-LD exhibited practical NRZ modulation characteristics at 10 Gb/s with a bias current of 20 mA and a modulation current amplitude of 30 mAp-p.

### Example 2

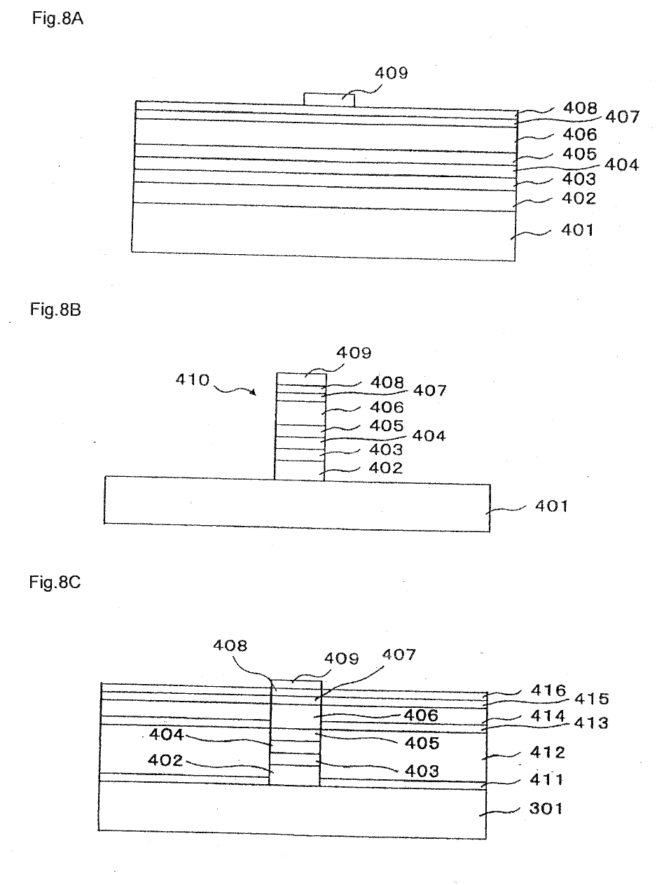

An example of a semiconductor optical filter used to verify the semiconductor device according to the first exemplary embodiment will be described below with reference to FIGS. 7A, 7B and 8A through 8C.

FIGS. 7A and 7B are cross-sectional views showing the structure of a semiconductor optical filter according to Example 2. FIG. 7A is a cross-sectional view taken along a direction perpendicular to the plane of a substrate, and FIG. 7B is a cross-sectional view taken along a direction parallel to the plane of the substrate.

As shown in FIG. 7A, the DFB-LD according to Example 2 includes mesastripe 410 comprising n-InP cladding layer 402, n-InGaAsP lower optical confinement layer 403, undoped InGaAsP strained multiple quantum well active layer 404, p-InGaAsP upper optical confinement layer 405, p-InP cladding layer 406, p-InGaAsP hetero-barrier relaxation layer 407, and p⁺-InGaAs contact layer 408 which are successively grown on n-InP substrate 401 of (001) orientation.

n-InP substrate 401 of (001) orientation is an example of a substrate. n-InP cladding layer 402 is an example of a cladding layer with a first electric conductivity. p-InP cladding layer 406 is an example of a cladding layer with a second electric conductivity. Mesastripe 410 is an example of a layered structure.

In the present example, n-InGaAsP lower optical confinement layer 403 has a wavelength composition of 1200 nm, undoped InGaAsP strained multiple quantum well active layer 404 has a transition wavelength of 1350 nm, p-InGaAsP upper optical confinement layer 405 has a wavelength composition of 1200 nm, and p-InGaAsP hetero-barrier relaxation layer 407 has a wavelength composition of 1400 nm.

As shown in FIG. 7B, mesastripe 410 has side walls formed with a grating having a periodic of 240 nm which is made up of an alternate repetition of surfaces parallel to (010) and (100) planes at respective intervals of 120 nm along (110) orientation. An effective stripe width produced by averaging the corrugation of the side walls is 1.3 μm.

An embedding layer which embeds both the side walls of mesastripe 410 comprises a set of p-InP electron trapping layer 411, Ru-doped semi-insulating InP current blocking layer 412, n-InP hole trapping layer 413, p-InP cladding layer 414, p-InGaAsP hetero-barrier relaxation layer 415, and p⁺-InGaAs contact layer 416.

Separation grooves 417 for reducing the device capacitance and electrically separating adjacent channels from each other are formed on both sides of mesastripe 410. SiO₂ films 418 are formed over separation grooves 417. Ti—Pt—Au electrodes 419, 420 are formed for injecting a carrier into undoped InGaAsP strained multiple quantum well active layer 404.

The cavity length is 300 μm with front and rear end faces coated with a low reflection film (not shown).

FIGS. 8A through 8C are cross-sectional views showing a method of manufacturing the semiconductor optical filter according to Example 2. FIG. 8A is a view showing a structure produced upon completion of a first epitaxial growth step, FIG. 8B is a view showing a structure processed into a stripe by etching, and FIG. 8C is a view showing a structure produced upon completion of an embedding growth step. The method of manufacturing the semiconductor optical filter according to Example 2 is the same as with Example 1, and will not be described in detail below.

The semiconductor optical filter according to the present example blocked the transmission of a signal light having a center wavelength of 1550 nm with an injected current of 0 mA, and had a stop bandwidth of 2 nm. When a current of 10 mA is injected, the center wavelength was shifted −1 nm.

### 2nd Exemplary Embodiment

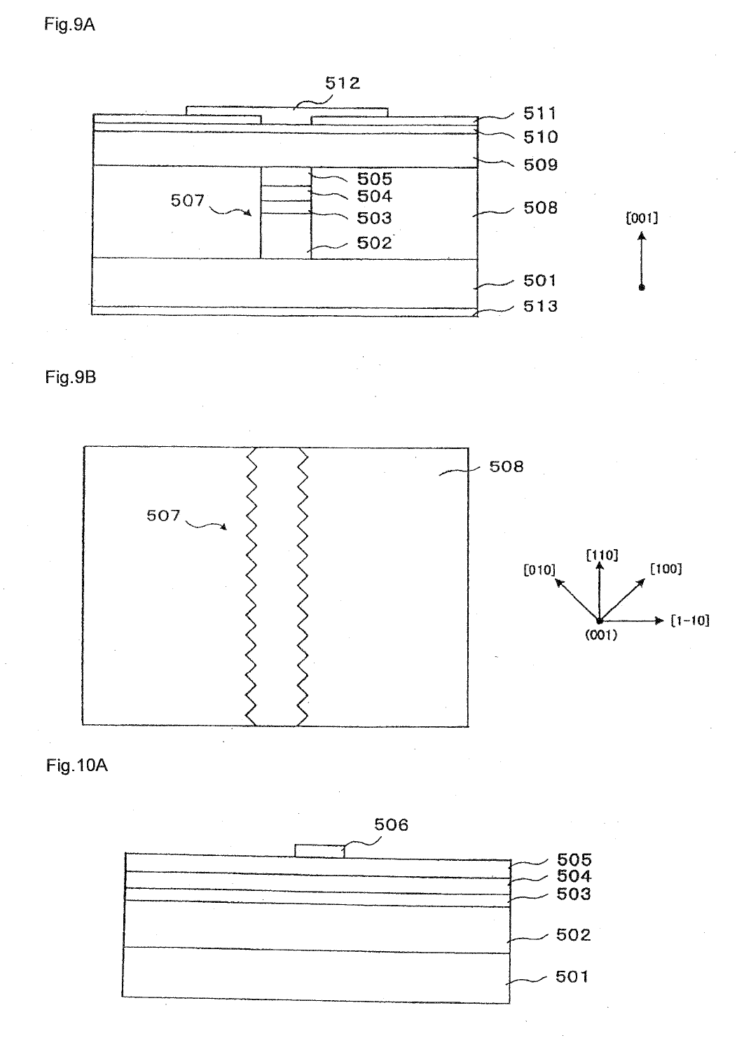

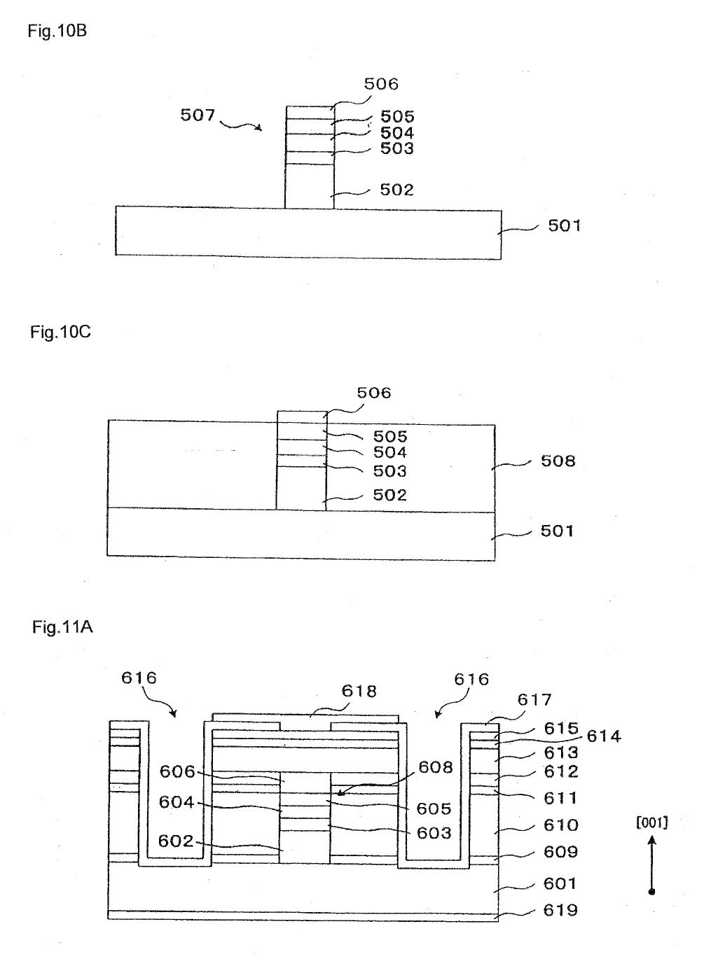

A second exemplary embodiment of the present invention will be described with reference to FIGS. 9A, 9B and 10A through 10C.

First, the structure of a semiconductor device according to the second exemplary embodiment will be described below.

FIGS. 9A and 9B are cross-sectional views of the structure of the semiconductor device according to the second exemplary embodiment. FIG. 9A is taken along a direction perpendicular to the plane of a substrate, and FIG. 9B along a direction parallel to the plane of the substrate.

As shown in FIG. 9A, the semiconductor device according to the second exemplary embodiment includes mesastripe 507 comprising optical confinement layer 502 with first second electric conductivity, undoped core layer 503, upper optical confinement layer 504 with a second electric conductivity, and cladding layer 505 with the second electric conductivity, which are successively grown on semiconductor substrate 501 of (001) orientation. Undoped core layer 503 is an example of an active layer, and mesastripe 507 is an example of a layered structure.

As shown in FIG. 9B, mesastripe 507 has side walls formed with a grating having a periodic structure which is made up of an alternate repetition of surfaces parallel to (010) and (100) planes. The side walls of mesastripe 507 are embedded with embedding layer 508 having a current blocking capability. Embedding cladding layer 509 and contact layer 510 having the second conductivity are grown on the upper surfaces of mesastripe 507 and embedding layer 508. Contact layer 510 has an upper surface covered with insulating film 511. Electrodes 512, 513 for injecting a carrier into undoped core layer 503 or applying an electric field to undoped core layer 503 are formed respectively on upper and lower surfaces of the semiconductor device. Semiconductor substrate 501 acts as a cladding layer with the first electric conductivity.

Embedding cladding layer 509 with second electric conductivity serves as an intermediate layer for reducing the contact resistance between mesastripe 507 and embedding layer 508, and contact layer 510 formed above these.

A method of manufacturing the semiconductor device according to the second exemplary embodiment will be described below.

FIGS. 10A through 10C are cross-sectional views illustrative of a method of manufacturing the semiconductor device according to the second exemplary embodiment. FIG. 10A is a view showing a structure produced upon completion of a first epitaxial growth step, FIG. 10B is a view showing a structure processed into a stripe by etching, and FIG. 10C is a view showing a structure produced upon completion of an embedding growth step.

First, as shown in FIG. 10A, optical confinement layer 502, undoped core layer 503, optical confinement layer 504, and cladding layer 505 are successively grown continuously on semiconductor substrate 501 to form mesastripe 507 by a first epitaxial growth step employing MOVPE or the like.

After a mask pattern, not shown, is transferred to mask 506 by a lithography such as electron beam exposure and reactive ion etching (RIE), a grating made up of an alternate repetition of surfaces parallel to (010) and (100) planes is formed on both side walls of mesastripe 507 by ICP-RIE or the like (FIG. 2510B).

Thereafter, as shown in FIG. 10C, embedding layer 508 is grown by a second epitaxial growth employing MOVPE or the like. An unwanted embedding layers formed in the actual embedding growth step are removed in the same manner as with the first exemplary embodiment.

After mask 506 is removed, embedding cladding layer 509 and contact layer 510 are successively grown continuously by a third epitaxial growth step using MOVPE or the like, and insulating film 511 is formed on the upper surface. Then, electrode 512 and electrode 513 are formed, thus completing the semiconductor device shown in FIGS. 9A and 9B.

Operation of the semiconductor device according to the second exemplary embodiment will be described below with reference to FIG. 9A.

When an electric current is injected into the semiconductor device from electrode 512 serving as an anode to electrode 513 as a cathode, holes are injected from optical confinement layer 504 into undoped core layer 503, and electrons are injected from optical confinement layer 502 into undoped core layer 503. The holes and the electrons are recombined with each other in undoped core layer 503, emitting light. Light having a particular wavelength which is determined by the periodic of the grating on the side walls of mesastripe 507 and the effective refractive index of mesastripe 507 is amplified, causing the semiconductor device to oscillate in a single longitudinal mode.

As described above, the present exemplary embodiment offers the same advantages as the first exemplary embodiment.

In the present exemplary embodiment, the manufacturing cost is increased because one more epitaxial growth step is added. However, as the etched depth is reduced when mesastripe 507 is processed, etching mask 506 is prevented from being unduly thinned, thus minimizing a reduction of the accuracy with which mesastripe 507 is processed. This is advantageous in realizing performances sensitive to the absolute dimensional accuracy of the device structure, such as a lasing wavelength, with high accuracy and high yield, and leads to a reduction of tolerances for manufacturing process conditions. Therefore, the present exemplary embodiment is expected to contribute to an effective yield increase and cost reduction.

### Example 3

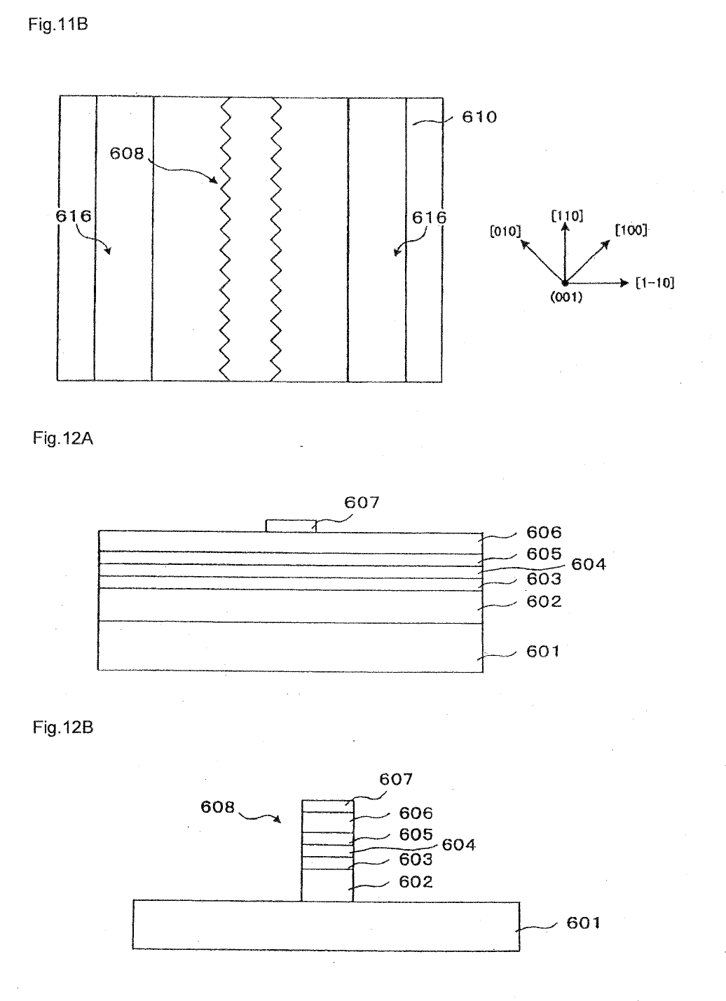

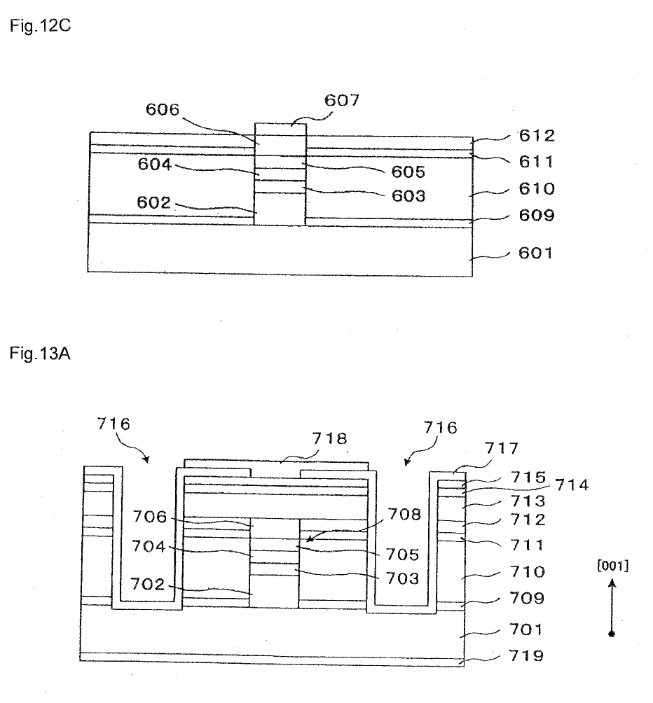

An example of a DFB-LD used to verify the semiconductor device according to the second exemplary embodiment will be described below with reference to FIGS. 11A, 11B and 12A through 12C.

First, the structure of the DFB-LD according to Example 3 will be described below.

FIGS. 11A and 11B are cross-sectional views showing the structure of the DFB-LD according to Example 3. FIG. 11A is a cross-sectional view taken along a direction perpendicular to the plane of a substrate, and FIG. 11B is a cross-sectional view taken along a direction parallel to the plane of the substrate.

As shown in FIG. 11A, the DFB-LD according to Example 3 includes mesastripe 608 comprising n-InP cladding layer 602, n-InGaAsP lower optical confinement layer 603, undoped InGaAsP strained multiple quantum well active layer 604, p-InGaAsP upper optical confinement layer 605, and p-InP cladding layer 606 which are successively grown on n-InP substrate 601 of (001) orientation.

n-InP substrate 601 of (001) orientation is an example of a substrate. n-InP cladding layer 602 is an example of a cladding layer with a first electric conductivity. p-InP cladding layer 606 is an example of a cladding layer with a second electric conductivity. Mesastripe 608 is an example of a layered structure.

In the present example, n-InGaAsP lower optical confinement layer 603 has a wavelength composition of 1250 nm, undoped InGaAsP strained multiple quantum well active layer 604 has a transition wavelength of 1560 nm, and p-InGaAsP upper optical confinement layer 605 has a wavelength composition of 1250 nm.

As shown in FIG. 11B, mesastripe 608 has side walls formed with a grating having a periodic of 240 nm which is made up of an alternate repetition of surfaces parallel to (010) and (100) planes at respective intervals of 120 nm along (110) orientation. An effective stripe width produced by averaging the corrugation of the side walls is 1.3 μm.

An embedding layer which embeds both the side walls of mesastripe 608 comprises a set of p-InP electron trapping layer 609, Ru-doped semi-insulating InP current blocking layer 610, n-InP hole trapping layer 611, and p-InP cladding layer 612.

On mesastripe 608 and the embedding layer, there are n-InP overcladding layer 613, which is an example of an embedding cladding layer with the second conductivity, p-InGaAsP hetero-barrier relaxation layer 614, and p⁺-InGaAs contact layer 615.

Separation grooves 616 for reducing the device capacitance and electrically separating adjacent channels from each other are formed on both sides of mesastripe 608. SiO₂ films 617 are formed over separation grooves 616. Ti—Pt—Au electrodes 618, 619 are formed for injecting a carrier into undoped InGaAsP strained multiple quantum well active layer 604.

The cavity length is 250 μm with a front end face coated with a low reflection film (not shown) and a rear end face coated with a high reflection film (not shown). The κL product is 1.2.

A method of manufacturing the DFB-LD according to Example 2 will be described below.

FIGS. 12A through 12C are cross-sectional views showing the method of manufacturing the DFB-LD according to Example 2. FIG. 12A is a view showing a structure produced upon completion of a first epitaxial growth step, FIG. 12B is a view showing a structure processed into a stripe by etching, and FIG. 12C is a view showing a structure produced upon completion of an embedding growth step.

First, n-InP cladding layer 602, n-InGaAsP lower optical confinement layer 603, undoped InGaAsP strained multiple quantum well active layer 604, p-InGaAsP upper optical confinement layer 605, and p-InP cladding layer 606 are successively grown continuously on n-InP substrate 601 to form mesastripe 608 by a first epitaxial growth step employing MOVPE.

Then, an SiO₂ film serving as etching mask 607 is patterned with high accuracy according to electron beam exposure and RIE (FIG. 12A). Then, the grating is formed with high accuracy according to ICP-RIE, as shown in FIG. 12B.

Thereafter, p-InP electron trapping layer 609, Ru-doped semi-insulating InP current blocking layer 610, n-InP hole trapping layer 611, and p-InP cladding layer 612 are successively grown continuously to form an embedding layer by a second epitaxial growth step employing MOVPE (FIG. 12C). An unwanted embedding layer that is grown as a thin layer on the side surfaces of mesastripe 310 upon embedding growth is removed in the same manner as with Example 1.

After mask 607 is removed, p-InP overcladding layer 613, p-InGaAsP hetero-barrier relaxation layer 614, and p⁺-InGaAs contact layer 615 are successively grown continuously by a third epitaxial growth step employing MOVPE.

The wafer is etched through the embedding layer on the sides of mesastripe 608, thereby forming separation grooves 616. Then, SiO₂ film 617 is formed on the upper surface, and subsequently removed primarily from the upper surface of mesastripe 608. Thereafter, Ti—Pt—Au electrodes 618, 619 are formed.

In this manner, the FDB-LD shown in FIGS. 11A and 11B is completed. When a carrier was injected into undoped InGaAsP strained multiple quantum well active layer 604, the FDB-LD oscillated in a single longitudinal mode with a threshold current of 5 mA and a lasing wavelength of 1550 nm at 250C. The FDB-LD exhibited practical NRZ modulation characteristics at 10 Gb/s with a bias current of 20 mA and a modulation current amplitude of 30 mAp-p.

### Example 4

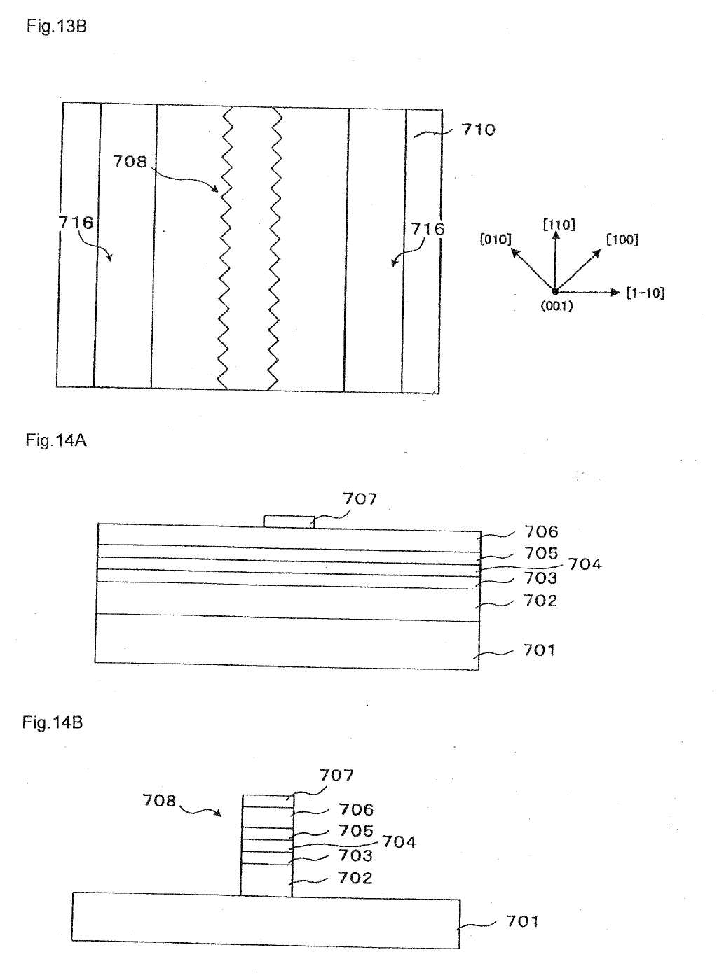

An example of a semiconductor optical filter used to verify the semiconductor device according to the second exemplary embodiment will be described below with reference to FIGS. 13A, 13B and 14A through 140.

First, the structure of a semiconductor optical filter according to Example 4 will be described below.

FIGS. 13A and 13B are cross-sectional views showing the structure of a semiconductor optical filter according to Example 4. FIG. 13A is a cross-sectional view taken along a direction perpendicular to the plane of a substrate, and FIG. 13B is a cross-sectional view taken along a direction parallel to the plane of the substrate.

As shown in FIG. 13A, the semiconductor optical filter according to Example 4 includes mesastripe 708 comprising n-InP cladding layer 702, n-InGaAsP lower optical confinement layer 703, undoped InGaAsP strained multiple quantum well active layer 704, p-InGaAsP upper optical confinement layer 705, and p-InP cladding layer 706 which are successively grown on n-InP substrate 701 of (001) orientation.

n-InP substrate 701 of (001) orientation is an example of a substrate n-InP cladding layer 702 is an example of a cladding layer with a first electric conductivity. p-InP cladding layer 706 is an example of a cladding layer with a second electric conductivity. Mesastripe 708 is an example of a layered structure.

In the present example, n-InGaAsP lower optical confinement layer 703 has a wavelength composition of 1200 nm, undoped InGaAsP strained multiple quantum well active layer 704 has a transition wavelength of 1350 nm, and p-InGaAsP upper optical confinement layer 705 has a wavelength composition of 1200 nm.

As shown in FIG. 13B, mesastripe 708 has side walls formed with a grating having a periodic of 240 nm which is made up of an alternate repetition of surfaces parallel to (010) and (100) planes at respective intervals of 120 nm along (110) orientation. An effective stripe width produced by averaging the corrugation of the side walls is 1.3 μm.

An embedding layer which embeds both the side walls of mesastripe 708 comprises a set of p-InP electron trapping layer 709, Ru-doped semi-insulating InP current blocking layer 710, n-InP hole trapping layer 711, and p-InP cladding layer 712.

On mesastripe 708 and the embedding layer, there are grown p-InP overcladding layer 713, p-InGaAsP hetero-barrier relaxation layer 714, and p⁺-InGaAs contact layer 715.

Separation grooves 716 for reducing the device capacitance and electrically separating adjacent channels from each other are formed on both sides of mesastripe 708. SiO₂ films 717 are formed over separation grooves 716. Ti—Pt—Au electrodes 718, 719 are formed for injecting a carrier into undoped InGaAsP strained multiple quantum well active layer 704.

The cavity length is 250 μm with front and rear end faces coated with a low reflection film (not shown).

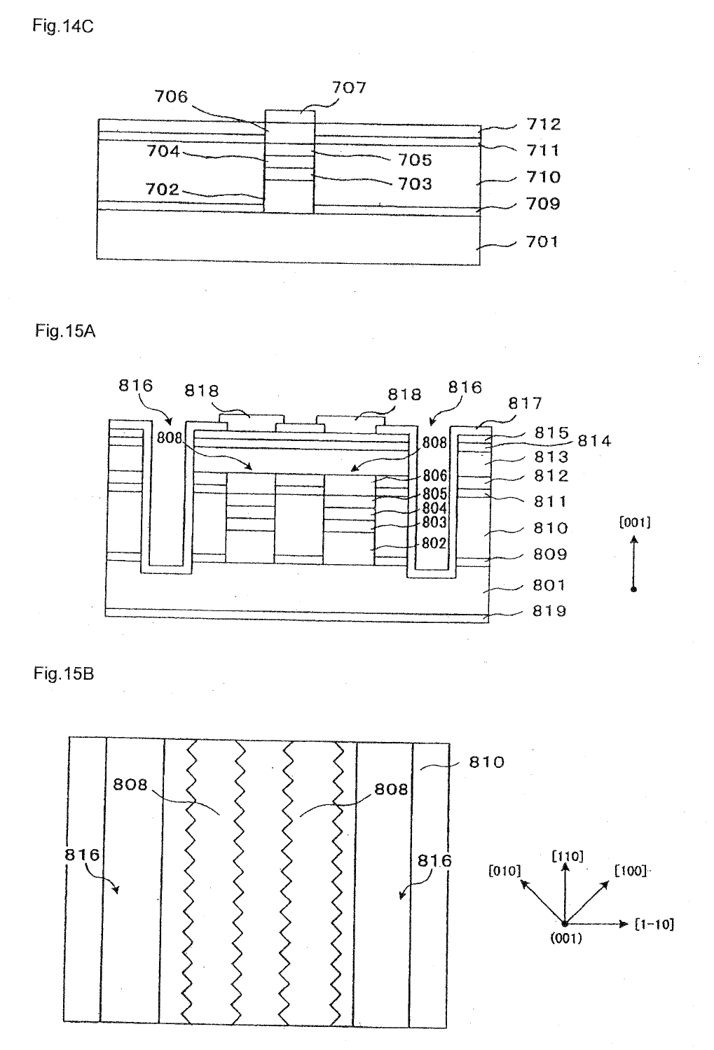

FIGS. 14A through 14C are cross-sectional views showing a method of manufacturing the semiconductor optical filter according to Example 4. FIG. 14A is a view showing a structure produced upon completion of a first epitaxial growth step, FIG. 14B is a view showing a structure processed into a stripe by etching, and FIG. 14C is a view showing a structure produced upon completion of an embedding growth step. The method of manufacturing the semiconductor optical filter according to Example 4 is the same as with Example 3, and will not be described in detail below.

The semiconductor optical filter according to the present example blocked the transmission of a signal light having a center wavelength of 1550 nm with an injected current of 0 mA, and had a stop bandwidth of 2 nm. When a current of 10 mA is injected, the center wavelength was shifted −1 nm.

### Example 5

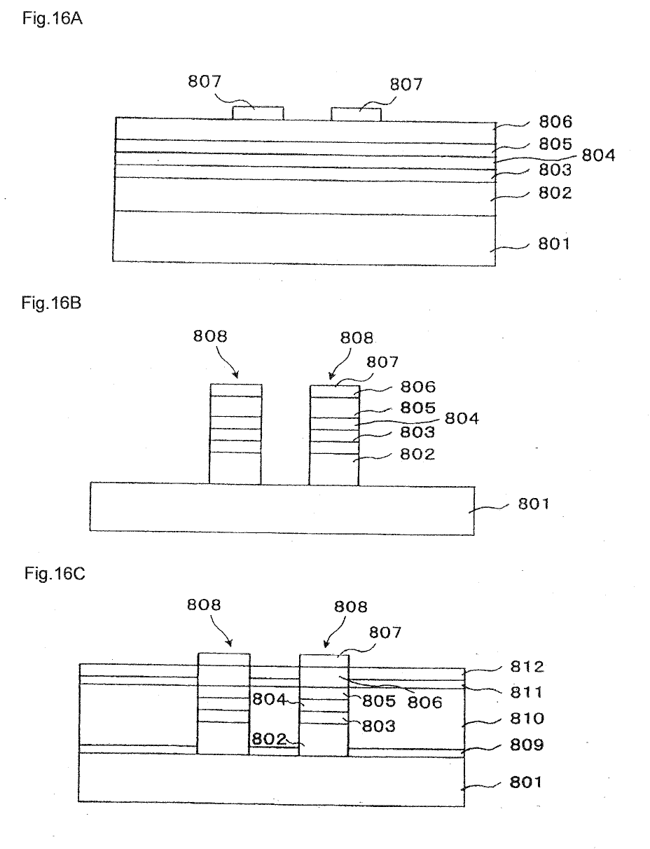

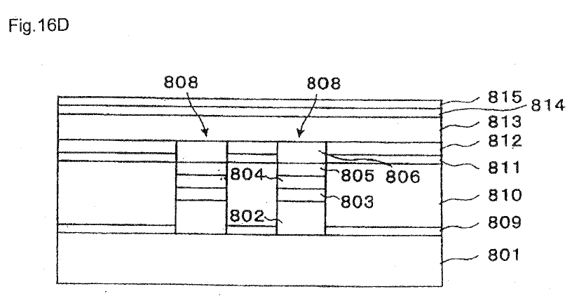

Another example of a semiconductor optical filter used to verify the semiconductor device according to the second exemplary embodiment will be described below with reference to FIGS. 15A, 15B and 16A through 16D.

First, the structure of a semiconductor optical filter according to Example 5 will be described below.

FIGS. 15A and 15B are cross-sectional views showing the structure of a semiconductor optical filter according to Example 5. FIG. 15A is a cross-sectional view taken along a direction perpendicular to the plane of a substrate, and FIG. 15B is a cross-sectional view taken along a direction parallel to the plane of the substrate.

As shown in FIG. 15A, the semiconductor optical filter according to Example 5 includes two mesastripes 808. Each of the mesastripes 808 comprises n-InP cladding layer 802, n-InGaAsP lower optical confinement layer 803, undoped InGaAsP strained multiple quantum well active layer 804, p-InGaAsP upper optical confinement layer 805, and p-InP cladding layer 806 which are successively grown on n-InP substrate 801 of (001) orientation.

Mesastripes 808 are an example of a layered structure. n-InP substrate 801 of (001) orientation is an example of a substrate. n-InP cladding layer 802 is an example of a cladding layer with a first electric conductivity. p-InP cladding layer 806 is an example of a cladding layer with a second electric conductivity.

In the present example, n-InGaAsP lower optical confinement layer 803 has a wavelength composition of 1200 nm, undoped InGaAsP strained multiple quantum well active layer 804 has a transition wavelength of 1350 nm, and p-InGaAsP upper optical confinement layer 805 has a wavelength composition of 1200 nm.

As shown in FIG. 15B, each mesastripe 808 has side walls formed with a grating having a periodic of 240 nm which is made up of an alternate repetition of surfaces parallel to (010) and (100) planes at respective intervals of 120 nm along (110) orientation. An effective stripe width produced by averaging the corrugation of the side walls is 1.3 μm. The distance between the center axes of mesastripes 808 is 2.8 μm.

An embedding layer which embeds both the side walls of each mesastripe 808 comprises a set of p-InP electron trapping layer 809, Ru-doped semi-insulating InP current blocking layer 810, n-InP hole trapping layer 811, and p-InP cladding layer 812.

On mesastripe 808 and the embedding layer, there are grown p-InP overcladding layer 813, which is an example of an embedding cladding layer with the second conductivity, p-InGaAsP hetero-barrier relaxation layer 814, and p⁺-InGaAs contact layer 815.

Separation grooves 816 for reducing the device capacitance and electrically separating adjacent channels from each other are formed on both sides of mesastripes 808. SiO₂ films 817 are formed over separation grooves 816. Ti—Pt—Au electrodes 818, 819 are formed for injecting a carrier into undoped InGaAsP strained multiple quantum well active layer 804.

The cavity length is 250 μm with front and rear end faces coated with a low reflection film (not shown).

FIGS. 16A through 16D are cross-sectional views showing a method of manufacturing the semiconductor optical filter according to Example 5. FIG. 16A is a view showing a structure produced upon completion of a first epitaxial growth step, FIG. 16B is a view showing a structure processed into a stripe by etching, FIG. 16C is a view showing a structure produced upon completion of an embedding growth step, and FIG. 16D is a view showing a structure produced upon completion of an electrode formation. The method of manufacturing the semiconductor optical filter according to Example 5 is the same as with Example 4, and will not be described in detail below.

The semiconductor optical filter according to the present example blocked the transmission of a signal light having a center wavelength of 1550 nm with an injected current of 0 mA, and the signal light which is blocked against transmission is reversely coupled to an optical waveguide on the opposite side. The semiconductor optical filter according to the present example had a stop bandwidth of 2 nm. When a current of 10 mA is injected, the center wavelength was shifted −1 nm.

In each of the above exemplary embodiments, a semi-insulating semiconductor doped with ruthenium is used as part of the embedding layer. However, a semi-insulating semiconductor doped with iron, for example, may be used.

In each of the above exemplary embodiments, the semiconductor device according to the present invention is verified with DFB-LDs and semiconductor optical filters. However, the present invention is also applicable to other semiconductor devices.

For example, the flat embedding growth according to a feature of the present invention, which is only made possible by defining the relative relationship between the crystalline plane orientations of the semiconductor substrate and the mesastripe side surfaces, is also highly useful to realize not only a DFB-LD which emits light by injecting a carrier into the active layer in the side surface grating forming area, but also a wavelength-tunable DBR-LD which only causes a change in the refractive index but does not emit light whether or not a carrier is injected into the side surface grating forming area.

The above advantage of flat embedding achieved by epitaxial growth is also highly useful to realize a semiconductor optical waveguide device which should employ a buried heterostructure for the reasons of characteristics or for the those of monolithic photonic integration with many devices, but which may not necessarily require a grating, e.g., a passive optical device such as a multimode interferometric optical multiplexer/demultiplexer or an active device such as an electroabsorption optical modulator, a Mach-Zehnder optical modulator, or the like.

It will be understood that the present invention is not limited to the above exemplary embodiments, but various changes and modifications may be made within the scope of the invention and should be interpreted as falling within the scope of the invention.

1-10. (canceled)

11. A semiconductor device comprising a layered mesa including a cladding layer with a first conductivity, an active layer, and a cladding layer with a second conductivity which are successively grown on a semiconductor substrate of (001) orientation, and an embedding layer covering both side surfaces of said layered mesa in a widthwise direction across a longitudinal direction of said layered mesa in a plane parallel to a surface of said semiconductor substrate, wherein
a portion of side surfaces of said active layer in said widthwise direction lies parallel to at least (010) or (100) surface.

12. The semiconductor device according to claim 11, wherein a first contact layer with said second conductivity is grown as an uppermost layer of said layered mesa;
a second contact layer with said second conductivity is grown as an uppermost layer of said embedding layer; and
said first contact layer and said second contact layer have side surfaces held against each other.

13. The semiconductor device according to claim 11, further comprising:
an embedding cladding layer with said second conductivity which covers upper surfaces of said layered mesa and said embedding layer.

14. The semiconductor device according to claim 11, wherein a structure comprising an alternate repetition of surfaces parallel to (010) and (100) surfaces is provided in a portion of side surfaces of said active layer in said widthwise direction.

15. The semiconductor device according to claim 12, wherein a structure comprising an alternate repetition of surfaces parallel to (010) and (100) surfaces is provided in a portion of side surfaces of said active layer in said widthwise direction.

16. The semiconductor device according to claim 13, wherein a structure comprising an alternate repetition of surfaces parallel to (010) and (100) surfaces is provided in a portion of side surfaces of said active layer in said widthwise direction.

17. The semiconductor device according to claim 11, wherein side surfaces of said layered mesa in widthwise direction are plane-symmetrical with respect to a plane extending through a longitudinal axis of said layered mesa and perpendicular to a surface of said semiconductor substrate.

18. The semiconductor device according to claim 12, wherein side surfaces of said layered mesa in widthwise direction are plane-symmetrical with respect to a plane extending through a longitudinal axis of said layered mesa and perpendicular to a surface of said semiconductor substrate.

19. The semiconductor device according to claim 13, wherein side surfaces of said layered mesa in widthwise direction are plane-symmetrical with respect to a plane extending through a longitudinal axis of said layered mesa and perpendicular to a surface of said semiconductor substrate.

20. The semiconductor device according to claim 11, wherein said embedding layer includes a semi-insulating semiconductor covering at least side surfaces of said active layer.

21. The semiconductor device according to claim 12, wherein said embedding layer includes a semi-insulating semiconductor covering at least side surfaces of said active layer.

22. The semiconductor device according to claim 13, wherein said embedding layer includes a semi-insulating semiconductor covering at least side surfaces of said active layer.

23. The semiconductor device according to claim 20, wherein said semi-insulating semiconductor contains at least iron or ruthenium.

24. The semiconductor device according to claim 21, wherein said semi-insulating semiconductor contains at least iron or ruthenium.

25. The semiconductor device according to claim 22, wherein said semi-insulating semiconductor contains at least iron or ruthenium.

26. A method of manufacturing a semiconductor device, comprising:
forming a layered structure including a structure comprising a cladding layer with a first conductivity, an active layer, and a cladding layer with a second conductivity which are successively grown on a semiconductor substrate of (001) orientation;
forming, on said layered structure, a mask for forming a predetermined pattern on said layered structure, said mask having a shape parallel to at least (010) or (100) surface in a portion of a side of said predetermined pattern in a widthwise direction across a longitudinal direction of said predetermined pattern in a plane parallel to a surface of said semiconductor substrate;
etching said layered structure from above said mask to form a layered mesa according to said predetermined pattern; and
forming an embedding layer covering both side surfaces of said layered mesa.

27. The method of manufacturing a semiconductor device according to claim 26, wherein when said embedding layer is formed, a semi-insulating semiconductor containing at least one of iron and ruthenium is formed in covering relation to at least side surfaces of said active layer.

28. The method of manufacturing a semiconductor device according to claim 27, wherein bisethylcyclopentadienyl ruthenium ((EtCp)2Ru) is used as a material of said ruthenium.
